(19) United States
(12) Patent Application Publication
(10) Pub. No.: US 2018/0021861 A1
(43) Pub. Date: Jan. 25, 2018

(54) DRILL STRUCTURE

(71) Applicant: TCT GLOBAL LIMITED, New Territories (HK)

(72) Inventors: Sung-Hao CHIEN, Taoyuan Hsien (TW); Li-Yi CHAO, Taoyuan Hsien (TW); Feng-Yu LIN, Taoyuan Hsien (TW); Ming-Yuan ZHAO, Taoyuan Hsien (TW); Chun-Yu CHEN, Taoyuan Hsien (TW)

(21) Appl. No.: 15/616,362

(22) Filed: Jun. 7, 2017

(30) Foreign Application Priority Data
Jul. 22, 2016 (TW) 105123221

(51) Int. Cl. B23B 51/02

(52) U.S. Cl. CPC B23B 51/02; B23B 2251/18; B23B 2251/408; B23B 2251/426; H05K 13/00

(57) ABSTRACT

A drill structure includes a shank part and a flute part arranged on one end of the shank part. A chisel edge is formed on the front end of the flute part and two drill blades with tilt directions toward the shank part are formed on the two sides of the chisel edge. Every drill blade includes a primary relief surface with a cutting edge and a secondary relief surface with a knife-back edge. At least one assist relief surfaces is formed on the inner wall of one of the two helical grooves and an included angle is between the assist relief surface and the horizontal plane. The assist relief surface is connected with the cutting edge of one drill blade and portion of the knife-back edge of another drill blade.

### BACKGROUND OF THE INVENTION

### 1. Field of the Invention

The present invention relates to a drill structure, and more particularly to a drill structure that is applicable to the printed circuit board (PCB).

### 2. Description of the Prior Art

In order to meet the highly competitive environment of the printed circuit board (PCB) of high quality, high demanding amount and fast supply in the market, the industry has higher and higher requirements for the processing conditions, such as the accuracy, strength and feed rate, and even the quality of the hole wall, of the micro drill that is used in the PCB drilling process. Moreover, in practice, the industry generally conducts the same drilling process for a plurality of stacked PCBs together to enhance the machining efficiency and reduce the manufacturing cost. Therefore, the used drill should have a longer length and also must have sufficient strength and scrap removal ability.

Thus, it is very necessary to develop a drill structure that has a good drilling performance and a good scrap removal performance, so as to adapt to the requirements of the high-speed, high-efficiency and automatic drilling.

### SUMMARY OF THE INVENTION

To solve the above problems, one purpose of the present invention is directed to provide a drill structure, which can reduce a thickness of a chisel edge with the structure of four relief surfaces and the inclined design of the assist relief surface, and can help to disperse the drilling resistance and reduce the wear of the relief surface, so as to increase the life of the spindle of the drilling flute part.

To achieve the above purpose, a drill structure of one embodiment of the present invention includes a shank part and a flute part arranged on one end of the shank part. A chisel edge is arranged at a front end of the flute part. A first drill blade and a second drill blade with tilt directions toward the shank part are formed on two sides of the chisel edge. A first outer circumference edge of the first drill blade and a second outer circumference edge of the second drill blade are extended and spiraled toward the shank part along a periphery of the flute part and form a first helical groove and a second helical groove respectively. The first drill blade includes a first primary relief surface and a first secondary relief surface. The first primary relief surface and the first secondary relief surface are connected to each other through a first ridge edge. The first primary relief surface has a first cutting edge. The first secondary relief surface has a first knife-back edge. The second drill blade includes a second primary relief surface and a second secondary relief surface. The second primary relief surface and the second secondary relief surface are connected to each other through a second ridge edge. The second secondary relief surface has a second knife-back edge. Moreover, the first cutting edge of the first primary relief surface and a portion of the second knife-back edge of the second secondary relief surface near the chisel edge extend and form a first assist relief surface that extends to an inner wall of the first helical groove.

In one embodiment, the second primary relief surface also has a second cutting edge, and the second cutting edge and a portion of the first knife-back edge of the first secondary relief surface near the chisel edge extend and form a second assist relief surface that extends to an inner wall of the second helical groove.

In addition, the first assist relief surface and the second assist relief surface may be inclined toward outward directions away from the chisel edge and have a groove profile, or the first assist relief surface and the second assist relief surface may be inclined toward directions toward a blade-tip static point and have a groove profile.

In one embodiment, the first knife-back edge and the second knife-back edge have a shape of a single arc or double arcs, and the first cutting edge and the second cutting edge have a shape of a straight line.

In one embodiment, the first cutting edge and the second cutting edge have a shape of a straight line, the first knife-back edge has a shape of a single arc or double arcs, and the second knife-back edge includes a straight line edge and an arc edge and is connected to the first cutting edge with the arc edge.

In one embodiment, the first cutting edge has a shape of a straight line, the first knife-back edge has a shape of a single arc or double arcs, and the second primary relief surface has a shape of a triangle. The second primary relief surface has the second ridge edge connected to the second secondary relief surface, a fourth ridge edge connected to the first secondary relief surface, and a first outer border edge. Two ends of the first outer border edge are respectively connected to one end of the second ridge edge away from the chisel edge and one end of the fourth ridge edge away from the chisel edge. The second secondary relief surface includes the second knife-back edge, the second outer circumference edge, the second outer border edge and the second ridge edge connected to the second primary relief surface.

In one embodiment, the first primary relief surface and the second secondary relief surface are intersected at the chisel edge as a third ridge edge, the second primary relief surface and the first secondary relief surface are intersected at the chisel edge as a fourth ridge edge, and a blade-tip static point of the flute part is formed by an intersection of the first ridge edge, the second ridge edge, the third ridge edge, and the fourth ridge edge. In addition, the first primary relief surface and the second primary relief surface are arranged symmetrically with respect to the blade-tip static point, and the first secondary relief surface and the second secondary relief surface are arranged symmetrically with respect to the blade-tip static point.

In one embodiment, the first outer circumference edge of the first drill blade spirals along the periphery of the flute part to form a helical cutting edge, and a portion of the first outer circumference edge of the first secondary relief surface near the first knife-back edge forms a lateral groove along the helical cutting edge.

### BRIEF DESCRIPTION OF THE DRAWINGS

FIG. 1 shows a schematic structure view of a drill structure of one embodiment of the present invention.

FIG. 2 shows a top view of one end face of a drill structure of a first embodiment of the present invention.

FIG. 3 shows a partial side view of the drill structure of the first embodiment of the present invention.

FIG. 4 shows a top view of one end face of a drill structure of a second embodiment of the present invention.

FIG. 5 shows a partial side view of the drill structure of the second embodiment of the present invention.

FIG. 6 shows a top view of one end face of a drill structure of a third embodiment of the present invention.

FIG. 7 shows a top view of one end face of a drill structure of a fourth embodiment of the present invention.

FIG. 8 shows a top view of one end face of a drill structure of a fifth embodiment of the present invention.

FIG. 9 shows a top view of one end face of a drill structure of a sixth embodiment of the present invention.

### DESCRIPTION OF THE PREFERRED EMBODIMENT

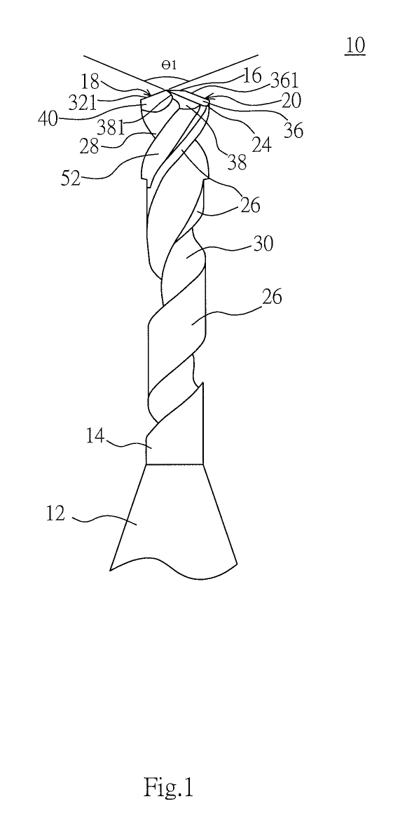

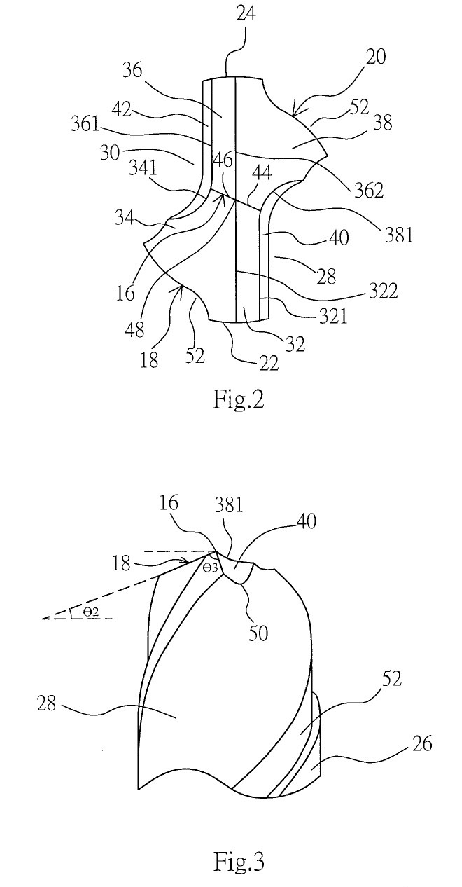

FIG. 1 shows a schematic structure view of a drill structure of one embodiment of the present invention, and FIG. 2 shows a top view of one end face of a drill structure of a first embodiment of the present invention. As shown in FIG. 1 and FIG. 2, a drill structure 10 includes a shank part 12 and a flute part 14. The flute part 14 is arranged on one end of the shank part 12, and a chisel edge 16 is arranged at a front end of the flute part 14. A first drill blade 18 and a second drill blade 20 with tilt directions toward the shank part 12 are formed on two sides of the chisel edge 16. In one embodiment, the first drill blade 18 and the second drill blade 20 construct a drill tip angle θ1, and the drill tip angle θ1 is between 100 degrees and 170 degrees. A first outer circumference edge 22 of the first drill blade 18 and a second outer circumference edge 24 of the second drill blade 20 are respectively extended and spiraled toward the shank part 12 along a periphery of the flute part 14 and form two helical cutting edges 26 and two helical groves. The two helical groves are a first helical groove 28 and a second helical groove 30 respectively.

The first drill blade 18 includes a first primary relief surface 32 and a first secondary relief surface 34. The first primary relief surface 32 has a first cutting edge 321, and the first primary relief surface 32 is connected to the first secondary relief surface 34 through a first ridge edge 322. The first secondary relief surface 34 has a first knife-back edge 341, and two ends of the first outer circumference edge 22 of the first drill blade 18 are respectively connected to one end of the first cutting edge 321 away from the chisel edge 16 and one end of the first knife-back edge 341 away from the chisel edge 16. In addition, the second drill blade 20 includes a second primary relief surface 36 and a second secondary relief surface 38. The second primary relief surface 36 has a second cutting edge 361, and the second primary relief surface 36 is connected to the second secondary relief surface 38 through a second ridge edge 362. The second secondary relief surface 38 has a second knife-back edge 381, and two ends of the second outer circumference edge 24 of the second drill blade 20 are respectively connected to one end of the second cutting edge 361 away from the chisel edge 16 and one end of the second knife-back edge 381 away from the chisel edge 16. In addition, the first cutting edge 321 and a portion of the second knife-back edge 381 near the chisel edge 16 extend and form a first assist relief surface 40 that extends to an inner wall of the first helical groove 28. Accordingly, the second cutting edge 361 and a portion of the first knife-back edge 341 near the chisel edge 16 extend and form a second assist relief surface 42 that extends to an inner wall of the second helical groove 30.

Continued with the foregoing descriptions, in the first embodiment, the first cutting edge 321 and the second cutting edge 361 have a shape of a straight line, and the first knife-back edge 341 and the second knife-back edge 381 have a shape of a single arc or double arcs. Furthermore, the first primary relief surface 32 and the second secondary relief surface 38 are intersected at the chisel edge 16 as a third ridge edge 44, and the second primary relief surface 36 and the first secondary relief surface 34 are intersected at the chisel edge 16 as a fourth ridge edge 46. A blade-tip static point 48 of the flute part 14 is formed by an intersection of the first ridge edge 322, the second ridge edge 362, the third ridge edge 44, and the fourth ridge edge 46. Furthermore, in the first embodiment, the first primary relief surface 32 and the second primary relief surface 36 are arranged symmetrically with respect to the blade-tip static point 48, and the first secondary relief surface 34 and the second secondary relief surface 38 are arranged symmetrically with respect to the blade-tip static point 48.

Referring to FIG. 3, FIG. 3 shows a partial side view of the drill structure of the first embodiment of the present invention. As shown in FIG. 3, the first drill blade 18 and the second drill blade 20 are inclined from the chisel edge 16 (shown in FIG. 1) toward both sides, and an inclined angle θ2 thereof is between 5 degrees and 30 degrees. In addition, the first assist relief surface 40 and the second assist relief surface 42 are inclined toward outward directions away from the chisel edge 16 respectively and have a groove profile 50. In FIG. 3, only the first assist relief surface 40 is shown and disclosed, and the second assist relief surface 42 is symmetrically arranged at the other side with respect to the blade-tip static point 48. An included angle θ3 is between the first assist relief surface 40 and a horizontal plane and between the second assist relief surface 42 and the horizontal plane, and the included angle θ3 is between 90 degrees and 180 degrees, which defines that the first assist relief surface 40 and the second assist relief surface 42 both have a negative inclined angle.

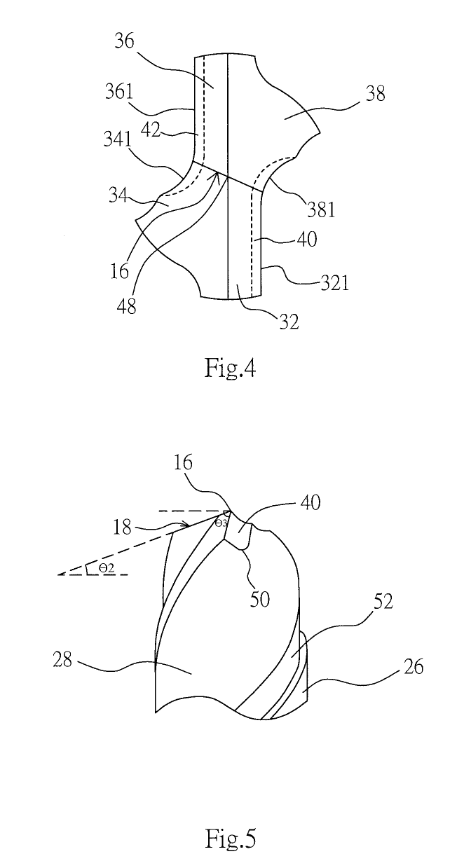

FIG. 4 shows a top view of one end face of a drill structure of a second embodiment of the present invention. The same as the first embodiment, the first primary relief surface 32 and the second primary relief surface 36 are arranged symmetrically with respect to the blade-tip static point 48, the first secondary relief surface 34 and the second secondary relief surface 38 are arranged symmetrically with respect to the blade-tip static point 48, the first cutting edge 321 and the second cutting edge 361 have a shape of a straight line, and the first knife-back edge 341 and the second knife-back edge 381 have a shape of a single arc or double arcs. Different from the first embodiment, in the second embodiment, as shown in FIG. 4 and FIG. 5, the first assist relief surface 40 and the second assist relief surface 42 are inclined toward inward directions toward the blade-tip static point 48 respectively and have a groove profile 50. In FIG. 5, only the first assist relief surface 40 is shown and disclosed, and the second assist relief surface 42 is symmetrically arranged at the other side with respect to the blade-tip static point 48. An included angle θ3 is between the first assist relief surface 40 and a horizontal plane and between the second assist relief surface 42 and the horizontal plane, and the included angle θ3 is between 0 degrees and 90 degrees, which defines that the first assist relief surface 40 and the second assist relief surface 42 both have a positive inclined angle.

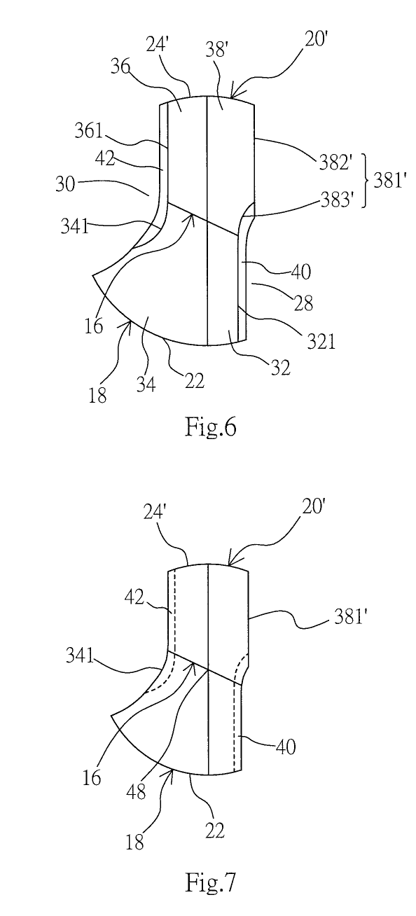

FIG. 6 shows a top view of one end face of a drill structure of a third embodiment of the present invention. As shown in FIG. 6, the first drill blade 18 and the second drill blade 20′ have different shapes. The first drill blade 18 includes a first primary relief surface 32 and a first secondary relief surface 34, and the second drill blade 20′ includes a second primary relief surface 36 and a second secondary relief surface 38′. In addition, the first cutting edge 321 of the first primary relief surface 32 and the second cutting edge 361 of the second primary relief surface 36 have a shape of a straight line, and the first knife-back edge 341 of the first secondary relief surface 34 has a shape of a single arc or double arcs. Two ends of the first outer circumference edge 22 are respectively connected to one end of the first cutting edge 321 away from the chisel edge 16 and one end of the first knife-back edge 341 away from the chisel edge 16. The second knife-back edge 381′ of the second secondary relief surface 38′ includes a straight line edge 382′ and an arc edge 383′ and is connected to the first cutting edge 321 with the arc edge 383′. Two ends of the second outer circumference edge 24′ are respectively connected to one end of the second cutting edge 361 away from the chisel edge 16 and one end of the second knife-back edge 381′ away from the chisel edge 16. In this embodiment, because the first knife-back edge 341 is different from the second knife-back edge 381′, so that the second outer circumference edge 24′ is shorter than the first outer circumference edge 22 and an area of the second drill blade 20′ is slightly less than an area of the first drill blade 18. Moreover, the first cutting edge 321 and the arc edge 383′ of the second knife-back edge 381′ extend and form a first assist relief surface 40 that extends to an inner wall of the first helical groove 28.

Accordingly, the second cutting edge 361 and a portion of the first knife-back edge 341 near the chisel edge 16 extend and form a second assist relief surface 42 that extends to an inner wall of the second helical groove 30. In the third embodiment, the first assist relief surface 40 and the second assist relief surface 42 are inclined toward outward directions away from the chisel edge 16 respectively and have a groove profile 50 (shown in FIG. 3), i.e., the first assist relief surface 40 and the second assist relief surface 42 both have the negative inclined angle as shown in FIG. 3.

FIG. 7 shows a top view of one end face of a drill structure of a fourth embodiment of the present invention. The same as the third embodiment, the first knife-back edge 341 has a shape of a single arc or double arcs and the second knife-back edge 381′ has a shape of a straight line, so that the second outer circumference edge 24′ is shorter than the first outer circumference edge 22, and an area of the second drill blade 20′ is slightly less than an area of the first drill blade 18. Different from the third embodiment, in the fourth embodiment, the first assist relief surface 40 and the second assist relief surface 42 are inclined toward inward directions toward the blade-tip static point 48 respectively and have a groove profile 50 (shown in FIG. 5), i.e., the first assist relief surface 40 and the second assist relief surface 42 both have the positive inclined angle as shown in FIG. 5.

In the above first, second, third and fourth embodiments, the first primary relief surface 32 and the second primary relief surface 36 are symmetrically arranged with respect to the blade-tip static point 48 and respectively have the first/second cutting edge of a shape of a straight line, and the first/second cutting edge and an adjacent portion of the second/first knife-back edge extend and form the first/second assist relief surface. In the above embodiments, a number of the assist relief surface is two, which is not a limitation, and one cutting edge and the adjacent knife-back edge thereof may extend and form the only one assist relief surface.

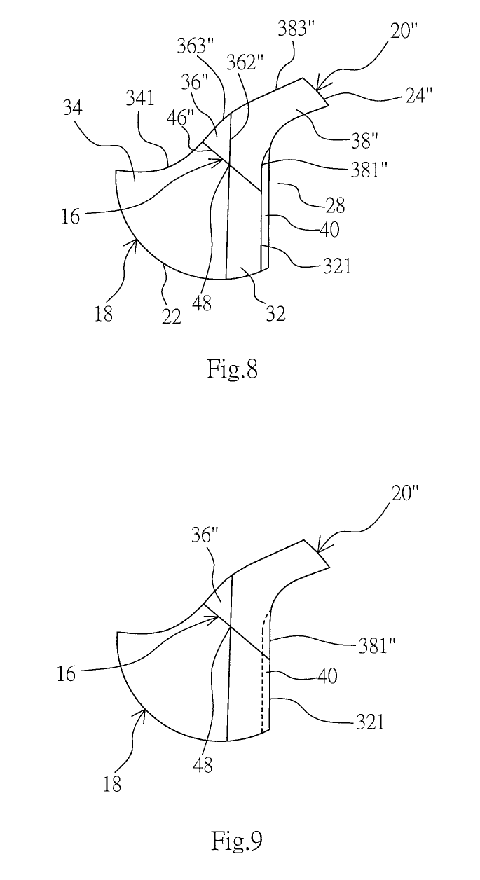

FIG. 8 shows a top view of one end face of a drill structure of a fifth embodiment of the present invention. As shown in FIG. 8, a first drill blade 18 and a second drill blade 20″ with tilt directions toward the shank part are formed on two sides of the chisel edge 16, and the first drill blade 18 includes a first primary relief surface 32 and a first secondary relief surface 34. In addition, the first cutting edge 321 has a shape of a straight line, and the first knife-back edge 341 has a shape of a single arc or double arcs. Two ends of the first outer circumference edge 22 are respectively connected to one end of the first cutting edge 321 away from the chisel edge 16 and one end of the first knife-back edge 341 away from the chisel edge 16.

Continued to refer to FIG. 8, the second drill blade 20″ includes a second primary relief surface 36″ and a second secondary relief surface 38″. The second primary relief surface 36″ almost has a shape of a triangle without the design of the cutting edge. The second primary relief surface 36″ has a second ridge edge 362″, a fourth ridge edge and a first outer border edge. The second ridge edge 362″ is connected to the second secondary relief surface 38″, and the fourth ridge edge 46″ is connected to the first secondary relief surface 34. One end of the second ridge edge 362″ away from the blade-tip static point 48 and one end of the fourth ridge edge 46″ away from the blade-tip static point 48 are connected to each other through the first outer border edge 363″. The second secondary relief surface 38″ and the second primary relief surface 36″ are connected to each other through the second ridge edge 362″. The second secondary relief surface 38″ further has a second knife-back edge 381″, a second outer border edge 383″ and a second outer circumference edge 24. The second knife-back edge 381″ has a shape of a single arc or double arcs. The second outer border edge 383″, the first outer border edge 363″ of the second primary relief surface 36″ and the second ridge edge 362″ are intersected to each other. Two end of the second outer circumference edge 24″ are respectively connected to one end of the second outer border edge 383″ and one end of the second knife-back edge 381″. The second outer circumference edge 24″ is shorter than the first outer circumference edge 22.

Continued with the foregoing descriptions, in the fifth embodiment, as shown in FIG. 8, the second primary relief surface 36″ does not have the design of the cutting edge, and an area of the second primary relief surface 36″ is far less than an area of the first primary relief surface 32. Moreover, the first assist relief surface 40 extends from the first cutting edge 321 and a portion of the second knife-back edge 381″ near the chisel edge 16 to an inner wall of the first helical groove 28, and the first assist relief surface 40 is inclined toward an outward direction away from the chisel edge 16 and has a groove profile 50 (shown in FIG. 3), i.e., the first assist relief surface has the negative inclined angle as shown in FIG. 3.

FIG. 9 shows a top view of one end face of a drill structure of a sixth embodiment of the present invention. The same as the fifth embodiment, the second primary relief surface 36″ of the second drill blade 20″ almost has a shape of a triangle without the design of the cutting edge, and the first assist relief surface 40 extends from the first cutting edge 321 and a portion of the second knife-back edge 381″ near the chisel edge 16 to an inner wall of the first helical groove 28. Different from the fifth embodiment, in the sixth embodiment, the first assist relief surface 40 is inclined toward an inward direction toward the blade-tip static point 48 and has a groove profile (shown in FIG. 5), i.e., the first assist relief surface 40 has the positive inclined angle as shown in FIG. 5.

In the above first to sixth embodiments, the front end of the flute part has the relief surface structure of four faces design, and has at least one assist relief surface that extends from the cutting edge and a portion of the knife-back edge to the helical groove. In addition, whether the assist relief surface has the positive inclined angle or the negative inclined angle, a width W of the assist relief surface is 20% to 80% of an outer diameter of the flute part, and preferably, 60% of the outer diameter of the flute part. Additionally, referring to FIG. 1 to FIG. 5, portions of the outer border edges of the first secondary relief surface 34 and the second secondary relief surface 38 respectively form a lateral groove 52 along the helical cutting edge 25. The lateral grooves 52 are respectively near the first knife-back edge 341 and the second knife-back edge 381, and the lateral grooves 52 are shorter than the first helical groove 28 and the second helical groove 30.

Furthermore, the flute part 14 may be divided into a front part, a middle part and a back part successively along a direction from the chisel edge 16 to the shank part 12. As shown in FIG. 1, the first helical groove 28 and the second helical groove 30 are separated symmetrically at the front part, gradually close to each other at the middle part, and overlapped at the back part. In addition, in one embodiment, a length of the first helical groove 28 may be different from that of the second helical groove 30, such that when the two grooves are overlapped until a position, one groove does not continue to extend and the other groove is retained to extend to the end of the flute part 14.

In addition, a material of the shank part 12 is stainless steel, and a material of the flute part 14 is tungsten carbide. In one embodiment, the shank part 12 and the flute part 14 are jointed together by welding or an adhesive. Also, in another embodiment, an inner hole (not shown) may be disposed in one end face of the shank part 12, and one end of the flute part 14 has a plug end (not shown). An inner diameter of the inner hole is less than or equal to the outer diameter of the plug end, and the plug end is pressed into and embedded in the inner hole, so as to joint the shank part 12 and the flute part 14. Or, the shank part 12 and the flute part 14 of the drill structure 10 may be integrally formed with the stick material of tungsten carbide as well.

In the present invention, the thickness of the chisel edge may be reduced with the inclined design of the assist relief surface, such that the drilling resistance may be reduced when using this drill structure to drill. Also, the four relief surfaces design of the relief surface structure may help to disperse the drilling resistance and reduce the wear of the relief surface, so as to increase the life of the spindle.

Although the present invention has been explained in relation to its preferred embodiment, it is to be understood that other modifications and variation can be made without departing the spirit and scope of the invention as hereafter claimed.

What is claimed is:

1. A drill structure comprising:
a shank part; and
a flute part arranged on one end of the shank part, a chisel edge arranged at a front end of the flute part, a first drill blade and a second drill blade with tilt directions toward the shank part formed on two sides of the chisel edge, a first outer circumference edge of the first drill blade and a second outer circumference edge of the second drill blade respectively helically extended around a periphery of the flute part toward the shank part to form a first helical groove and a second helical groove respectively, the first drill blade comprising a first primary relief surface and a first secondary relief surface, the first primary relief surface and the first secondary relief surface connected to each other through a first ridge edge, the first primary relief surface having a first cutting edge, the first secondary relief surface having a first knife-back edge, the second drill blade comprising a second primary relief surface and a second secondary relief surface, the second primary relief surface and the second secondary relief surface connected to each other through a second ridge edge, the second secondary relief surface having a second knife-back edge, wherein the first cutting edge of the first primary relief surface and a portion of the second knife-back edge of the second secondary relief surface near the chisel edge extend and form a first assist relief surface that extends to an inner wall of the first helical groove.

2. The drill structure according to claim 1, wherein the first assist relief surface is inclined toward an outward direction away from the chisel edge and has a groove profile, or the first assist relief surface is inclined toward a direction toward a blade-tip static point and has a groove profile.

3. The drill structure according to claim 1, wherein the second primary relief surface has a second cutting edge, and the second cutting edge and a portion of the first knife-back edge of the first secondary relief surface near the chisel edge extend and form a second assist relief surface that extends to an inner wall of the second helical groove.

4. The drill structure according to claim 3, wherein the second assist relief surface is inclined toward an outward direction away from the chisel edge and has a groove profile, or the second assist relief surface is inclined toward a direction toward a blade-tip static point and has a groove profile.

5. The drill structure according to claim 3, wherein the first knife-back edge and the second knife-back edge have a shape of a single arc or double arcs, the first cutting edge and the second cutting edge have a shape of a straight line, two ends of the first outer circumference edge are respectively connected to one end of the first cutting edge away from the chisel edge and one end of the first knife-back edge away from the chisel edge, and two ends of the second outer circumference edge are respectively connected to one end of the second cutting edge away from the chisel edge and one end of the second knife-back edge away from the chisel edge.

6. The drill structure according to claim 3, wherein the first cutting edge and the second cutting edge have a shape of a straight line, the first knife-back edge has a shape of a single arc or double arcs, two ends of the first outer circumference edge are respectively connected to one end of the first cutting edge away from the chisel edge and one end of the first knife-back edge away from the chisel edge, the second knife-back edge includes a straight line edge and an arc edge and is connected to the first cutting edge with the arc edge, two ends of the second outer circumference edge are respectively connected to one end of the second cutting edge away from the chisel edge and one end of the second knife-back edge away from the chisel edge, and the second outer circumference edge is shorter than the first outer circumference edge.

7. The drill structure according to claim 1, wherein the first primary relief surface and the second secondary relief surface are intersected at the chisel edge as a third ridge edge, the second primary relief surface and the first secondary relief surface are intersected at the chisel edge as a fourth ridge edge, and a blade-tip static point of the flute part is formed by an intersection of the first ridge edge, the second ridge edge, the third ridge edge, and the fourth ridge edge.

8. The drill structure according to claim 7, wherein the first primary relief surface and the second primary relief surface are arranged symmetrically with respect to the blade-tip static point, and the first secondary relief surface and the second secondary relief surface are arranged symmetrically with respect to the blade-tip static point.

9. The drill structure according to claim 1, wherein the first cutting edge has a shape of a straight line; the first knife-back edge has a shape of a single arc or double arcs; two ends of the first outer circumference edge are respectively connected to one end of the first cutting edge away from the chisel edge and one end of the first knife-back edge away from the chisel edge; the second primary relief surface has a shape of a general triangle; the second primary relief surface has the second ridge edge connected to the second secondary relief surface, a fourth ridge edge connected to the first secondary relief surface, and a first outer border edge; two ends of the first outer border edge are respectively connected to one end of the second ridge edge away from the chisel edge and one end of the fourth ridge edge away from the chisel edge; the second secondary relief surface includes the second knife-back edge, the second outer circumference edge, a second outer border edge and the second ridge edge connected to the second primary relief surface; and the second outer circumference edge is shorter than the first outer circumference edge.

10. The drill structure according to claim 1, wherein the first outer circumference edge of the first drill blade helically extended around the periphery of the flute part toward the shank part to form a helical cutting edge, and a lateral grooves is formed along the helical cutting edge from a portion of the first outer circumference edge of the first secondary relief surface adjacent to the first knife-back edge.
